(19) United States
(12) Patent Application Publication
(10) Pub. No.: US 2021/0092828 A1
(43) Pub. Date: Mar. 25, 2021

(54) CIRCUIT UNIT, ELECTRICAL JUNCTION BOX, AND PRODUCTION METHOD OF CIRCUIT UNIT

(71) Applicant: Sumitomo Wiring Systems, Ltd., Yokkaichi-shi (JP)

(72) Inventor: Yoshikazu Sasaki, Yokkaichi-shi (JP)

(21) Appl. No.: 17/025,136

(22) Filed: Sep. 18, 2020

(30) Foreign Application Priority Data
Sep. 19, 2019 (JP) 2019-169937

(51) Int. Cl. H05K 1/02; H05K 7/14; H05K 3/28

(52) U.S. Cl. CPC H05K 1/0203; H05K 2203/1147; H05K 3/285; H05K 7/1427

(57) ABSTRACT

A circuit unit includes a circuit section that has terminal portions connectable to external terminals and main body portions on which electronic components are mounted, and in which portions between the main body portions and the terminal portions are portions to be waterproofed that are made of plate-shaped metals. First waterproofing portions are in intimate contact with the portions to be waterproofed of the circuit section, and are made of resin containing an adhesive component. A second waterproofing portion is made of resin and is in intimate contact with outer surfaces of the circuit section and the first waterproofing portions. The portions to be waterproofed each include recessed portions into which the first waterproofing portion can enter, and protruding portions protruding outward are formed on an outer surface of a portion of each first waterproofing portion overlapping the recessed portions.

### CROSS-REFERENCE TO RELATED APPLICATIONS

This application claims priority of Japanese Patent Application No. JP 2019-169937 filed on Sep. 19, 2019, the contents of which are incorporated herein.

### TECHNICAL FIELD

The present specification discloses a technique for inhibiting entry of water into a circuit.

### BACKGROUND

Conventionally, techniques for waterproofing the interior of a unit in which a circuit is accommodated are known. According to the technique described in JP 2004-31416A, a power circuit section disposed on a heat dissipation member via an insulating layer is covered by a waterproof case, and the waterproof case is provided with a hood for each connector for connection to the outside. A waterproofing portion that is filled with an epoxy resin is formed around the external connection terminal inside the hood, and the waterproofing portion prevents water from entering the waterproof case along the external connection terminal.

### SUMMARY

Although the waterproofing portion is provided around the external connection terminal inside the hood portion in the configuration of JP 2004-31416A described above, a portion around a bus bar, which is formed continuously with the external connection terminal, inside the waterproof case is not covered by the waterproof structure. Accordingly, there is a concern that water may enter the inside of the waterproof case from the interface between the external connection terminal and the waterproofing portion.

The technique described in the present specification has been completed in view of the above-described circumstances, and an object thereof is to inhibit entry of water from a terminal portion side to an electronic component side.

A circuit unit disclosed in the present specification includes: a circuit section that includes a terminal portion connectable to an external terminal and a main body portion on which an electronic component is mounted, and in which a portion between the main body portion and the terminal portion is a portion to be waterproofed that is made of a plate-shaped metal; a first waterproofing portion that is in intimate contact with the portion to be waterproofed of the circuit section, and that is made of resin containing an adhesive component; and a second waterproofing portion that is made of resin, and that is in intimate contact with the circuit section and an outer surface of the first waterproofing portion, wherein the portion to be waterproofed includes a recessed portion into which the first waterproofing portion can enter, and a protruding portion protruding outward is formed on an outer surface of a portion of the first waterproofing portion that overlaps the recessed portion.

A production method of a circuit unit disclosed in the present specification includes: a first waterproofing step of bringing a first waterproofing portion made of resin containing an adhesive component into intimate contact with a plate-shaped metal portion to be waterproofed that is provided between a terminal portion connectable to an external terminal and an electronic component in a circuit section that includes the terminal portion and a main body portion on which the electronic component is mounted; and a second waterproofing step of bringing resin into intimate contact with the circuit section and the first waterproofing portion, wherein, in the first waterproofing step, the resin containing the adhesive component enters a recessed portion formed in the portion to be waterproofed, and a protruding portion protruding outward is formed on the outer surface of the first waterproofing portion in the region of the recessed portion.

According to the technique disclosed in the present specification, it is possible to inhibit entry of water from a terminal portion side to an electronic component side.

### BRIEF DESCRIPTION OF THE DRAWINGS

FIG. 1 is a plan view showing an electrical junction box according to an embodiment.

FIG. 2 is a cross-sectional view taken along line A-A of FIG. 1.

FIG. 3 is a plan view showing a bus bar.

FIG. 4 is a rear view showing the bus bar.

FIG. 5 is a right side view showing the bus bar.

FIG. 6 is a perspective view showing a first molded product in which a first waterproofing portion is formed on the bus bar.

FIG. 7 is a plan view showing the first molded product in which the first waterproofing portion is formed on the bus bar.

FIG. 8 is an enlarged rear view showing a part of the first molded product in which the first waterproofing portion is formed on the bus bar.

FIG. 9 is a cross-sectional view taken along line B-B of FIG. 8.

FIG. 10 is a right side view showing the first molded product in which the first waterproofing portion is formed on the bus bar.

FIG. 11 is a perspective view showing a second molded product.

FIG. 12 is a bottom view showing the second molded product.

### DETAILED DESCRIPTION OF PREFERRED EMBODIMENTS

First, embodiments of the present disclosure will be listed and described.

A circuit unit of present disclosure includes: a circuit section that includes a terminal portion connectable to an external terminal and a main body portion on which an electronic component is mounted, and in which a portion between the main body portion and the terminal portion is a portion to be waterproofed that is made of a plate-shaped metal; a first waterproofing portion that is in intimate contact with the portion to be waterproofed of the circuit section, and that is made of resin containing an adhesive component; and a second waterproofing portion that is made of resin, and that is in intimate contact with the circuit section and an outer surface of the first waterproofing portion, wherein the portion to be waterproofed includes a recessed portion into which the first waterproofing portion can enter, and a protruding portion protruding outward is formed on an outer surface of a portion of the first waterproofing portion that overlaps the recessed portion.

According to the above configuration, because the water flowing along the terminal portion is waterproofed by the resin of the second waterproofing portion and is waterproofed by the first waterproofing portion made of resin containing an adhesive component, it is possible to suppress the water from entering the main body portion side from the terminal portion side. In addition, because the position of the first waterproofing portion with respect to the portion to be waterproofed is easily maintained by the first waterproofing portion entering the recessed portion, it is possible to suppress the positional displacement of the first waterproofing portion. Incidentally, if the second waterproofing portion is formed by the second molding after the first waterproofing portion is formed, it is assumed that a portion of the first waterproofing portion is melted by heat of the resin in a molten state at the time of the second molding and a force is applied to the first waterproofing portion by pressure of the resin in a molten state. Here, in the configuration in which the recessed portion is formed in the portion to be waterproofed, there is the advantage that the position of the first waterproofing portion can be maintained by the recessed portion. However, the melted first waterproofing portion easily moves in the recessed portion or the like, and there is a concern that the thickness of the first waterproofing portion covering the portion to be waterproofed is reduced due to the movement of the first waterproofing portion, or a portion not covered by the first waterproofing portion is generated in the portion to be waterproofed, and the waterproofing property may be degraded. On the other hand, according to the above configuration, because the thickness of the portion that overlaps the recessed portion of the portion to be waterproofed is increased due to the protruding portion of the first waterproofing portion, even when the first waterproofing portion in the recessed portion melts and moves due to heat or pressure at the time of second molding, a waterproof thickness of the first waterproofing portion covering the portion to be waterproofed can be easily ensured, and the deterioration of the waterproofing property of the portion to be waterproofed by the first waterproofing portion can be suppressed.

The width of the protruding portion may be larger than a range of the recessed portion that overlaps the protruding portion.

With this configuration, even when the first waterproofing portion melts and moves, it is possible to suppress a decrease in waterproofing property due to size of the protruding range of the protruding portion.

The recessed portion and the protruding portion may be provided on both surfaces of a plate surface of the portion to be waterproofed.

With this configuration, it is possible to suppress deterioration of waterproofing property on both surfaces of the plate surface of the portion to be waterproofed.

The recessed portion may be a through hole that penetrates the portion to be waterproofed.

With this configuration, it is possible to further suppress the displacement of the first waterproofing portion due to heat and pressure at the time of the second molding. Also, the thickness of the first waterproofing portion in the region of the through hole can be increased.

The terminal portion may have a width dimension larger than that of a portion of the circuit section with which the first waterproofing portion is in intimate contact.

With this configuration, in a configuration in which it is not easy to attach a packing made of rubber or the like due to size of the width dimension of the terminal portion, waterproofing can be achieved without using the packing.

A portion between the terminal portion and the main body portion in the circuit section may be bent in a crank shape.

With this configuration, in a configuration in which there is a concern about adhesion to the portion to be waterproofed during resin molding because the circuit section has a crank shape, it is possible to suppress entry of water from the outside.

The circuit section may include a plate-shaped metal bus bar, the terminal portion and the portion to be waterproofed are formed on the bus bar, and the first waterproofing portion and the second waterproofing portion may be in intimate contact with the bus bar.

With this configuration, it is possible to prevent water from entering the bus bar through which a relatively large current flows.

An electrical junction box includes the circuit unit, a heat dissipation member that is superposed on the circuit unit, and a sealing member that is sandwiched between the circuit unit and the heat dissipation member.

A production method of a circuit unit of the present disclosure includes: a first waterproofing step of bringing a first waterproofing portion made of resin containing an adhesive component into intimate contact with a plate-shaped metal portion to be waterproofed that is provided between a terminal portion connectable to an external terminal and an electronic component in a circuit section that includes the terminal portion and a main body portion on which the electronic component is mounted; and a second waterproofing step of forming a second waterproofing portion by bringing resin into intimate contact with the circuit section and the first waterproofing portion, wherein, in the first waterproofing step, the resin containing the adhesive component enters a recessed portion formed in the portion to be waterproofed, and a protruding portion protruding outward is formed on the outer surface of the first waterproofing portion in the region of the recessed portion.

According to the above configuration, because the water flowing along the terminal portion is waterproofed by the resin of the second waterproofing portion and is waterproofed by the first waterproofing portion made of resin containing an adhesive component, it is possible to suppress the water from entering the main body portion side from the terminal portion side. In addition, because the position of the first waterproofing portion with respect to the portion to be waterproofed is easily maintained by the first waterproofing portion entering the recessed portion, it is possible to suppress the positional displacement of the first waterproofing portion. Incidentally, if the second waterproofing portion is formed by the second molding after the first waterproofing portion is formed, it is assumed that a portion of the first waterproofing portion is melted by heat of the resin in a molten state at the time of the second molding and a force is applied to the first waterproofing portion by pressure of the resin in a molten state. Here, in the configuration in which the recessed portion is formed in the portion to be waterproofed, there is the advantage that the position of the first waterproofing portion can be maintained by the recessed portion. However, the melted first waterproofing portion easily moves in the recessed portion or the like, and there is a concern that the thickness of the first waterproofing portion covering the portion to be waterproofed is reduced due to the movement of the first waterproofing portion, or a portion not covered by the first waterproofing portion is generated in the portion to be waterproofed, and the waterproofing property may be degraded. On the other hand, according to the above configuration, because the thickness of the portion that overlaps the recessed portion of the portion to be waterproofed is increased due to the protruding portion of the first waterproofing portion, even when the first waterproofing portion in the recessed portion melts and moves due to heat or pressure at the time of the second molding, a waterproof thickness of the first waterproofing portion covering the portion to be waterproofed can be easily ensured, and the waterproofed state of the portion to be waterproofed by the first waterproofing portion can be maintained.

Specific examples of the present disclosure will be described below with reference to the drawings. Note, that the present disclosure is not limited to these exemplifications, is indicated by the scope of the claims, and is intended to include meanings equivalent to the scope of the claims and all modifications within the scope.

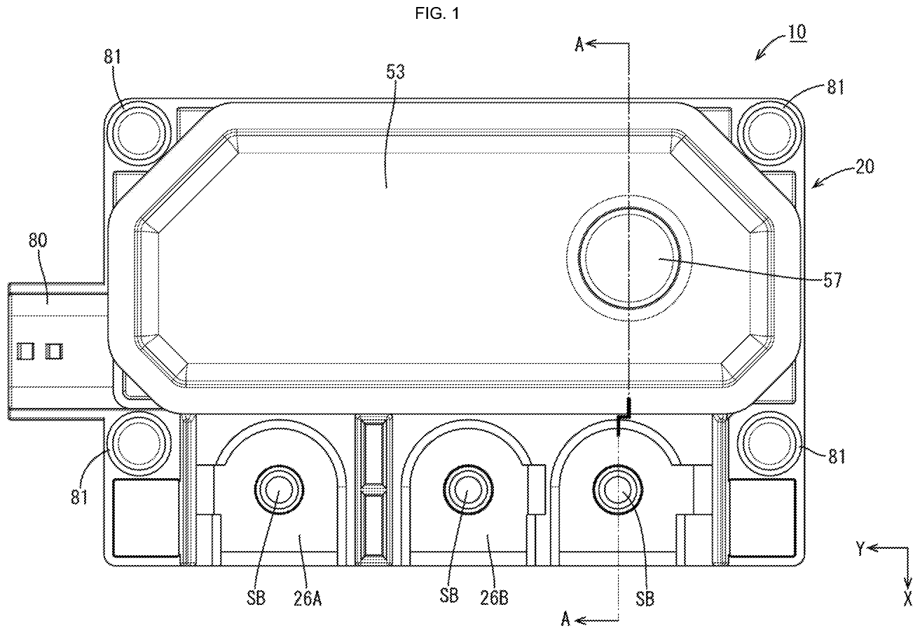

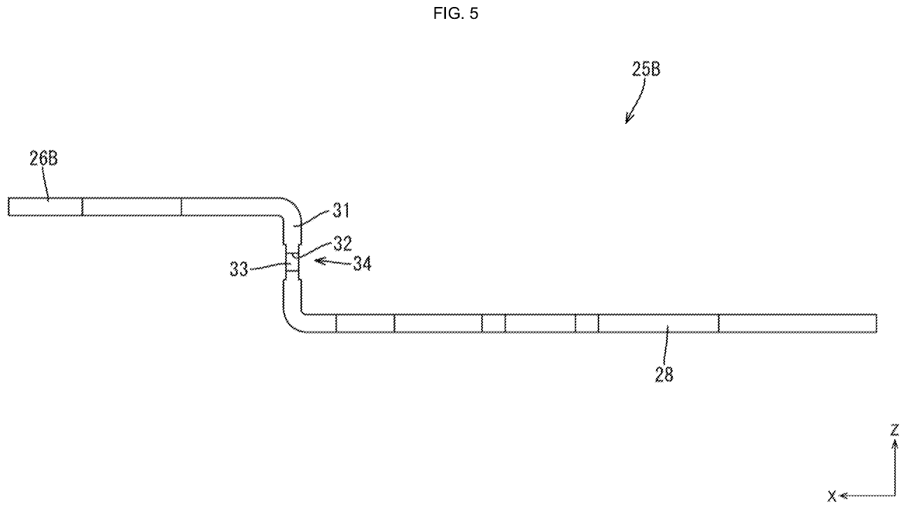

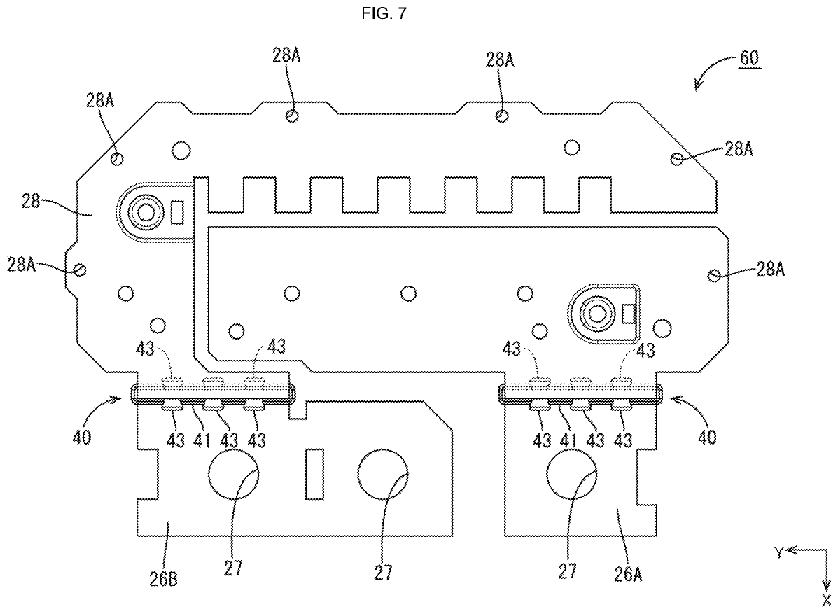

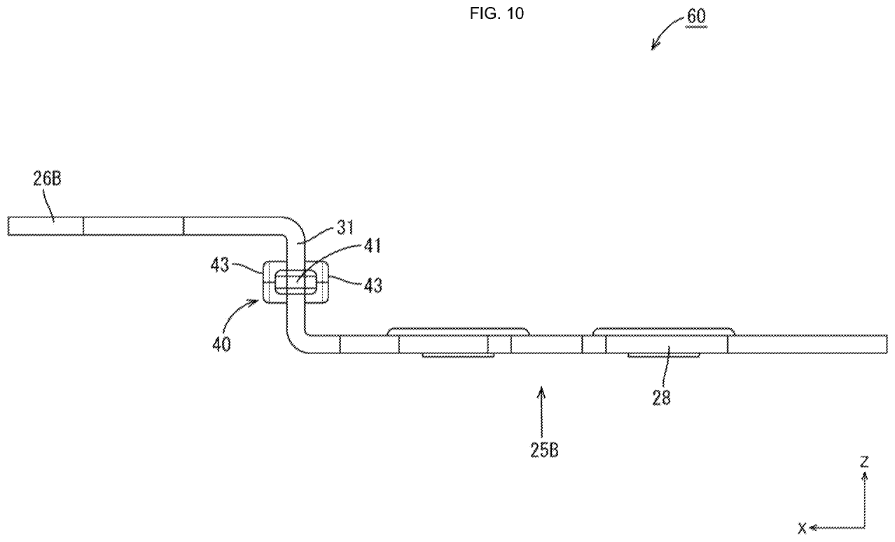

The present embodiment will be described with reference to FIGS. 1 to 12.

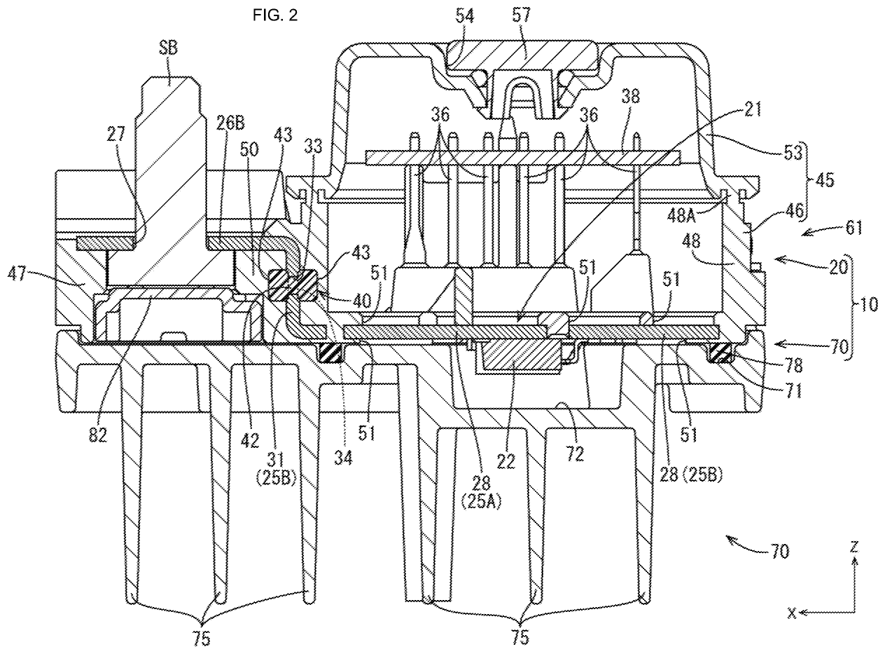

An electrical junction box 10 is disposed, for example, in a power supply path between a power supply, such as a battery, and a load including an on-board electrical component such as a lamp or a drive motor of a vehicle, which may be an electric vehicle, a hybrid vehicle, or a gasoline vehicle. Although the electrical junction box 10 can be disposed in any orientation, in the following description, the X direction and the Y direction in FIG. 1 are respectively referred to as frontward and leftward, and the Z direction in FIG. 2 is referred to as upward.

As shown in FIG. 2, the electrical junction box 10 includes a circuit unit 20, and a heat dissipation member 70 that is superposed below the circuit unit 20 and dissipates heat of the circuit unit 20. The circuit unit 20 includes a circuit section 21 formed by mounting electronic components 22 on bus bars 25A and 25B, first waterproofing portions 40 that are in intimate contact with portions to be waterproofed 34 of the bus bars 25A and 25B and that are made of resin containing an adhesive component, and a resin portion 45 that is in intimate contact with the bus bars 25A and 25B and the first waterproofing portions 40 and that forms a case of the circuit unit 20.

The circuit section 21 includes a plurality of electronic components 22 that generate heat when current flows through them, and a pair (plurality) of bus bars 25A and 25B. In the present embodiment, the electronic components 22 are mounted side by side in the left-right direction on the back surfaces of the bus bars 25A and 25B, and are relays such as FETs (Field Effect Transistors). The electronic components 22 are not limited to relays, and may also be resistors, coils, capacitors, or the like, for example. Each electronic component 22 includes a plurality of lead terminals connected to the bus bars 25A and 25B. One lead terminal is provided in the region of the upper surface of the electronic component 22 and is soldered to the bus bar 25A, and the plurality of other lead terminals protrude from the side surface of the electronic component 22 and are soldered to the bus bar 25B.

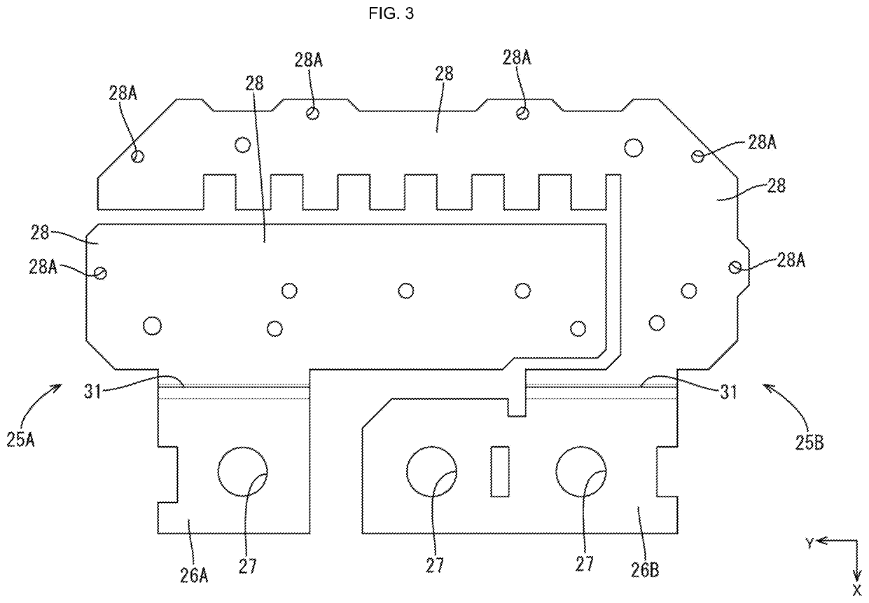

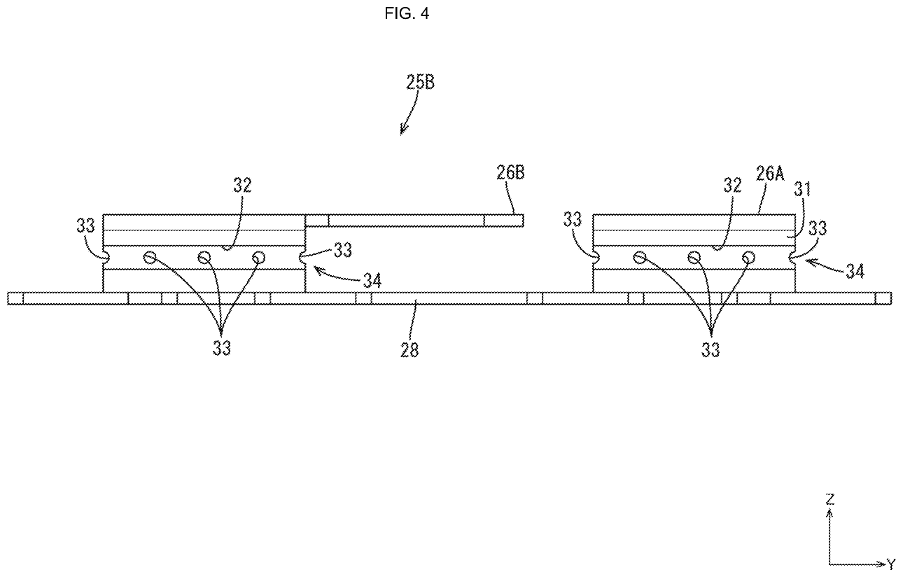

Each of the bus bars 25A and 25B is made of a flat metal plate material such as copper or a copper alloy, and as shown in FIGS. 3 and 4, has a shape corresponding to the current path, and is plated on the outer surface, for example. The pair of bus bars 25A and 25B are disposed with a gap between them. The bus bars 25A and 25B respectively include terminal portions 26A and 26B connectable to external terminals, and each include a main body portion 28 on which the electronic components 22 are mounted, and a connection portion 31 for respectively connecting the terminal portions 26A and 26B and the main body portion 28 in a crank shape (when viewed from the side).

The terminal portions 26A and 26B have a rectangular shape, and bolt insertion holes 27 through which the shaft portions of stud bolts SB are inserted are formed through the terminal portions 26A and 26B, respectively. The width dimension of one terminal portion 26B is larger than the width dimension of the connection portion 31. The lead terminal of each electronic component 22 is soldered to the main body portion 28 of the bus bar 25A, and other lead terminals of each electronic component 22 are soldered to the main body portion 28 of the bus bar 25B. A plurality of holes 28A penetrating in a circular shape are disposed at intervals in the circumferential edge portions of the main body portions 28. The holes 28A can be filled with the resin of the resin portion 45, for example.

The connection portions 31 have plate surfaces in a direction respectively orthogonal to the plate surfaces of the terminal portions 26A and 26B and the main body portions 28, and intermediate portions of the connection portions 31 in the up-down direction (current flowing direction) are portions to be waterproofed 34, as shown in FIG. 4. Each of the portions to be waterproofed 34 is a region to which a first waterproofing portion 40 described later is in intimate contact, and a groove-shaped groove portion 32 is provided over the entire circumference of the connection portion 31. A plurality of through holes 33 penetrating the groove portion 32 are formed in the bottom surface of the groove portion 32. In the present embodiment, the plurality of through holes 33 include three circular through holes 33 and two semicircular through holes 33 for each connection portion 31. The plurality of through holes 33 are disposed at predetermined intervals in the left-right direction. The resin forming the first waterproofing portion 40 enters and fills the through holes 33 at the time of the first molding. The number of through holes 33 may be changed as appropriate. Two circular through holes 33 may also be provided in each connection portion 31, for example.

As shown in FIG. 2, a control circuit board 38 is disposed above the bus bars 25A and 25B to face the bus bars 25A and 25B. The control circuit board 38 is a printed circuit board in which conductive paths (not shown) made of copper foil or the like are formed on an insulating plate made of an insulating material by a printed wiring technique. The control circuit board 38 and the bus bars 25A and 25B are electrically connected to each other via rod-shaped relay terminals 36. The relay terminals 36 are inserted into the through holes of the control circuit board 38 and the bus bars 25A and 25B and soldered, for example. The bus bars 25A and 25B have a thickness (and a cross-sectional area) larger than that of the relay terminal 36. By increasing the thickness (and the cross-sectional area) of the bus bars 25A and 25B, the thermal conductivity is increased and the electric resistance is decreased, and the heat generated by the electronic components 22 is diffused into the bus bars 25A and 25B and is made uniform. The bus bars 25A and 25B are connected to connector terminals (not shown) of a connector 80 (see FIG. 1) by soldering or the like.

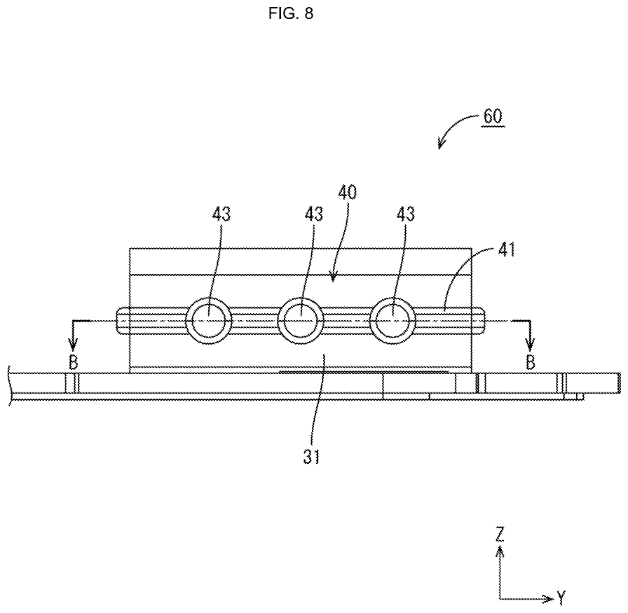

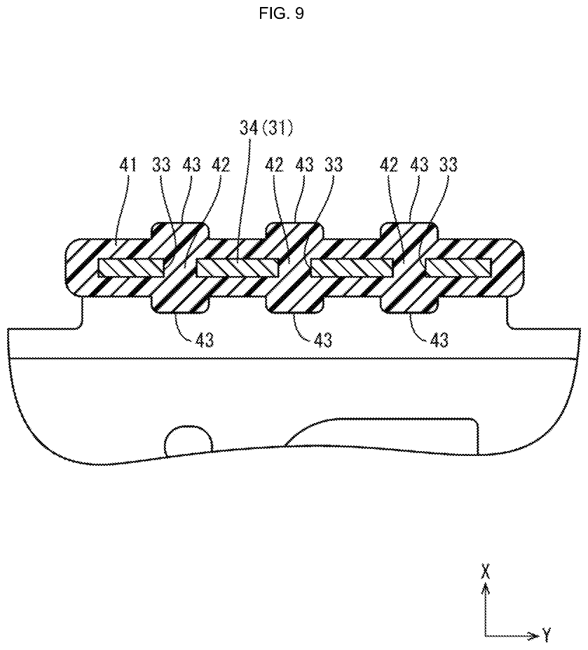

As shown in FIGS. 8 and 9, the first waterproofing portions 40 include waterproof main bodies 41 that are in intimate contact with the outer circumferences of the portions to be waterproofed 34 of the bus bars 25A and 25B, and a plurality of protruding portions 43 that protrude from the waterproof main bodies 41. Each waterproof main body 41 is superposed on the portion to be waterproofed 34 with a substantially constant thickness, and includes filling portions 42 filled in the plurality of through holes 33 at the positions of the through holes 33 in the portion to be waterproofed 34. The protruding portions 43 are provided in a columnar shape at positions overlapping the through holes 33 (and the filling portions 42) of the first waterproofing portion 40. The circumferential edge of the distal end of each protruding portion 43 is notched and rounded. The first waterproofing portions 40 function as interface waterproof materials for waterproofing the interfaces between the bus bars 25A and 25B, and include a polyester-based elastomer resin as a main component and an adhesive component. The polyester-based elastomer resin contains a reactive group to be bonded to an oxide film of a metal, has characteristics of both rubber and engineering plastic, and is excellent in, for example, flexibility, heat resistance, and thermal adhesiveness to a hard resin. As the adhesive component, for example, a silicon-based adhesive, an epoxy-based adhesive, a polyurethane-based adhesive, a polyester-based adhesive, a cyanoacrylate-based adhesive, an acrylic-based adhesive, or the like can be used.

As shown in FIG. 2, the resin portion 45 includes a resin body 46 and a resin cover 53 that covers an opening 48A of the resin body 46. The resin body 46 includes a second waterproofing portion 50 that is in intimate contact with the outer surfaces of the first waterproofing portions 40 and the regions of the bus bars 25A and 25B other than the portions to be waterproofed 34, a rectangular tubular circumferential wall portion 48 that surrounds the regions of the main body portions 28 of the bus bars 25A and 25B, and bolt holding portions 47 that hold the head portions of the stud bolts SB. The resin portion 45 can be formed of various resin materials such as polyphenylenesulfide (PPS), polybutylene terephthalate (PBT), nylon, polypropylene (PP), and polyethylene (PE), and does not contain an adhesive component. The resin material of the resin portion 45 may also contain a filler such as glass fiber.

The second waterproofing portion 50 is formed integrally with the circumferential wall portion 48 and the bolt holding portions 47, extends along the plate surfaces of the bus bars 25A and 25B, and is in intimate contact with the outer surfaces of the bus bars 25A and 25B and the outer surfaces of the first waterproofing portions 40. In the second waterproofing portion 50, a plurality of exposure holes 51 for partially exposing the upper surfaces and the lower surfaces of the main body portions 28 are formed at positions overlapping the main body portions 28 of the bus bars 25A and 25B.

The bolt holding portions 47 have the bus bars 25A and 25B fixed thereto, and expose the terminal portions 26A and 26B. In a state where the shaft portion of the stud bolt SB is inserted into the corresponding bolt insertion hole 27, the stud bolt SB is held by the bolt holding portion 47 together with a terminal block 82, and the terminal portions 26A and 26B and external terminals (not shown) are fastened by nuts (not shown).

The resin cover 53 is joined to the opening 48A at the upper end of the circumferential wall portion 48 by thermal welding, and the space in the circumferential wall portion 48 is sealed by the welding of the resin cover 53 to be waterproofed. The resin cover 53 is provided with a mounting hole 54 through which a ventilation valve 57 is mounted. The ventilation valve 57 includes a ventilation film that allows the passage of air and prevents the passage of moisture, and is provided with fine holes that are waterproof, dustproof, and that provide ventilation.

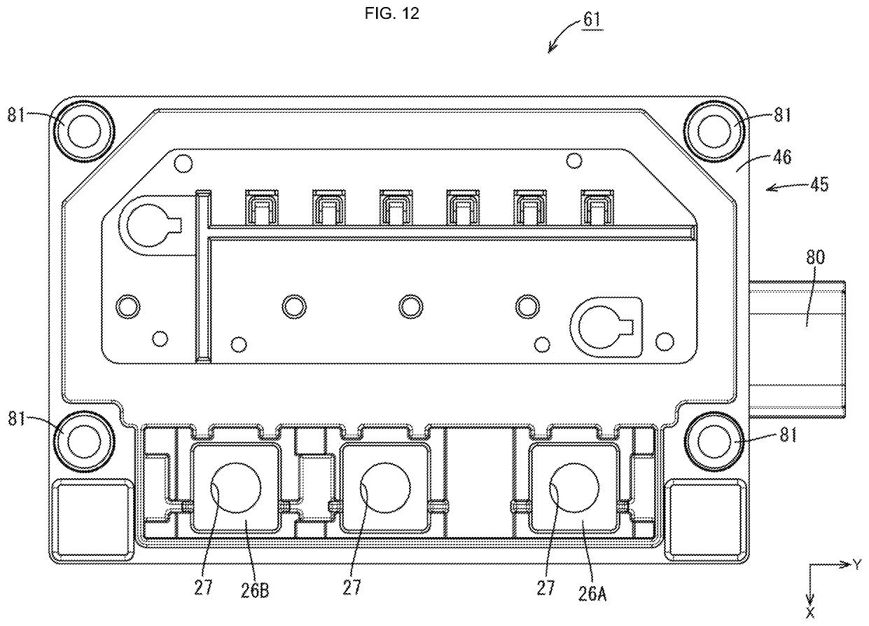

As shown in FIG. 12, fastening portions 81 are fixed to the resin body 46 at positions near the four corners of the resin body 46 to be screwed and fixed to the heat dissipation member 70 with screws (not shown). The fastening portions 81 are formed of, for example, cylindrical metal collars into which shaft portions of screws are inserted, and are embedded in the resin body 46.

As shown in FIG. 2, the heat dissipation member 70 is made of a metal material having high thermal conductivity such as aluminum, an aluminum alloy, copper, an copper alloy, or the like, and a plurality of heat dissipation fins 75 are arranged on the lower surface side of the heat dissipation member 70. A sealing member accommodating groove 71 into which a sealing member 78 is fitted and accommodating chambers 72 in which the electronic components 22 are accommodated are formed on the upper surface of the heat dissipation member 70. The sealing member accommodating groove 71 extends annularly, surrounding the main body portions 28. A heat transfer material (not shown) is disposed between the upper surface of the heat dissipation member 70 and the lower surface of the circuit unit 20. As the heat transfer material, a synthetic resin or the like having insulating properties and high thermal conductivity is used, and, a heat dissipation adhesive made of an epoxy resin or the like can be used for example.

A production method of the electrical junction box 10 will be described next.

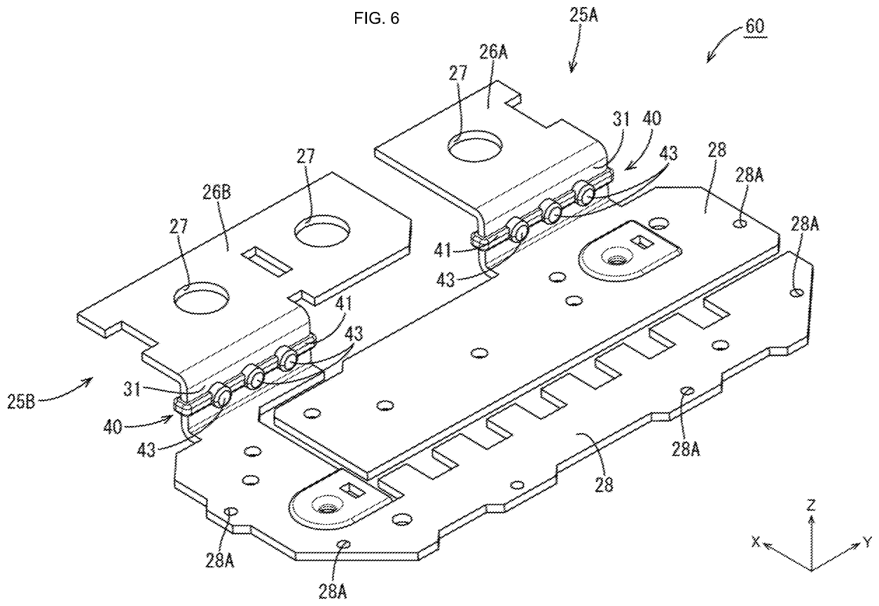

After the plurality of bus bars 25A and 25B (FIG. 3) are formed by punching and bending a metal plate by a press machine, a first waterproofing step is performed. In the first waterproofing step, the bus bars 25A and 25B are placed in a mold (not shown), a liquid polyester-based elastomer resin containing an adhesive component is injected into the mold, and the polyester-based elastomer resin is removed from the mold after being solidified. As a result, a first molded product 60 in which the first waterproofing portions 40 are formed on the bus bars 25A and 25B is formed (FIG. 6).

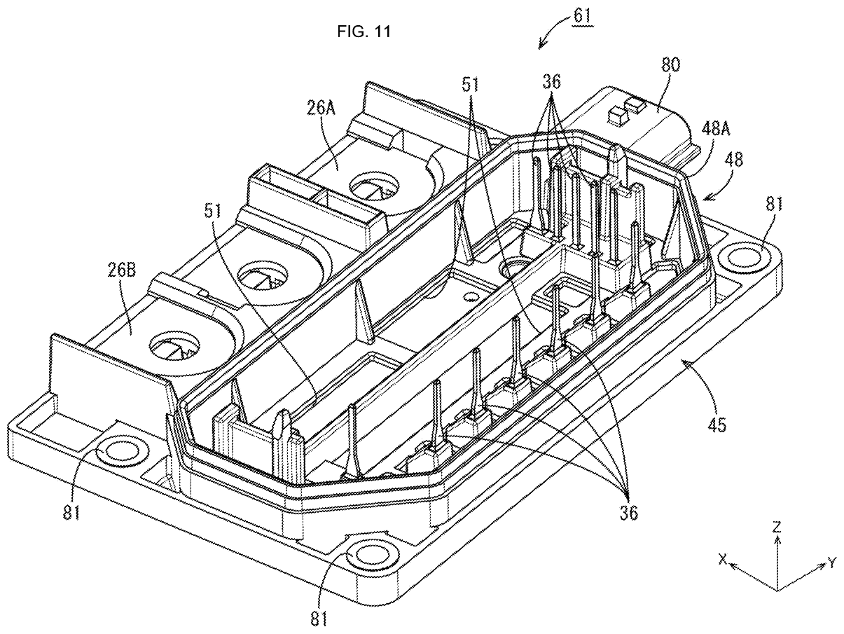

Next, a second waterproofing step is performed on the first molded product 60. In the second waterproofing step, the first molded product 60 and the relay terminals 36 are placed in a mold (not shown), and insert molding is performed in which a liquid synthetic resin is injected into the mold from an injection hole of the mold to form a second molded product 61 (FIG. 11).

Here, the temperature of the synthetic resin injected in the second waterproofing step is higher than the melting point of the elastomer resin of the first waterproofing portion 40. Due to the heat of the synthetic resin, the first waterproofing portions 40 are partially melted and deformed, and the first waterproofing portions 40 slightly flow. Because the through holes 33 are formed in the portions to be waterproofed 34, the elastomer resin is easily melted and moved at the positions of the through holes 33. In the present embodiment, because the thickness of the first waterproofing portions 40 is increased by the protruding portions 43 of the first waterproofing portions 40, it is possible to delay the time until the first waterproofing portions 40 melt. In addition, due to the thickness of the protruding portions 43, it is possible to suppress a decrease in waterproofing property caused by the first waterproofing portions 40 being melted and partially thinned or a portion of the portions to be waterproofed 34 not covered with the first waterproofing portions 40 being generated.

Next, an annealing step of heating the second molded product 61 is performed. In the annealing step, the elastomer resin of the first waterproofing portions 40 is re-melted by heating, and an oxidized film of the metal and the reactive group are chemically bonded to each other, whereby the adhesion between the outer surfaces of the portions to be waterproofed 34 and the first waterproofing portions 40 can be improved.

The operation and effects of the present embodiment will be described next.

A circuit unit 20 includes: a circuit section 21 that has terminal portions 26A and 26B connectable to external terminals and main body portions 28 on which electronic components 22 are mounted, and in which portions between the main body portions 28 and the terminal portions 26A and 26B are portions to be waterproofed 34 that are made of plate-shaped metals; first waterproofing portions 40 that are in intimate contact with the portions to be waterproofed 34 of the circuit section 21, and that are made of resin containing an adhesive component; and a second waterproofing portion 50 that is made of resin and that is in intimate contact with the circuit section 21 and an outer surface of the first waterproofing portions 40, wherein the portions to be waterproofed 34 each include through holes 33 (an example of recessed portions) into which the first waterproofing portion 40 can enter, and protruding portions 43 protruding outward are formed on an outer surface of a portion of each first waterproofing portion 40 that overlaps the through holes 33.

According to the present embodiment, because the water flowing along the terminal portions 26A and 26B is waterproofed by the resin of the second waterproofing portion 50 and is waterproofed by the first waterproofing portions 40 made of resin containing an adhesive component, it is possible to suppress the water from entering the main body portions 28 side from the terminal portions 26A and 26B side. In addition, because the positions of the first waterproofing portions 40 with respect to the portions to be waterproofed 34 are easily maintained by the first waterproofing portions 40 entering the through holes 33, it is possible to suppress the positional displacement of the first waterproofing portions 40.

Incidentally, if the second waterproofing portion 50 is formed by the second molding after the first waterproofing portions 40 are formed, it is assumed that a portion of the first waterproofing portions 40 is melted by heat of the resin in a molten state at the time of the second molding and a force is applied to the first waterproofing portions 40 by pressure of the resin in a molten state. Here, in the configuration in which the through holes 33 are formed in the portions to be waterproofed 34, there is the advantage that the positions of the first waterproofing portions 40 can be maintained by the through holes 33. However, the melted first waterproofing portions 40 easily move in the through holes 33, and there is a concern that the thickness of the first waterproofing portions 40 covering the portions to be waterproofed 34 is reduced due to the movement of the resin of the first waterproofing portions 40, or a portion not covered by the first waterproofing portions 40 is generated in the portions to be waterproofed 34, and the waterproofing property may be degraded. On the other hand, according to the embodiment, because the thickness of the portions overlapping the through holes 33 of the portions to be waterproofed 34 is increased due to the protruding portions 43 of the first waterproofing portions 40, even when the first waterproofing portions 40 in the through holes 33 melt and move due to heat or pressure at the time of the second molding, a waterproof thickness of the first waterproofing portions 40 covering the portions to be waterproofed 34 can be easily ensured, and the deterioration of the waterproofing property of the portions to be waterproofed 34 by the first waterproofing portions 40 can be suppressed.

The widths of the protruding portions 43 is larger than ranges of the through holes 33 that overlap the protruding portions 43.

With this configuration, even when the first waterproofing portions 40 melt and move, it is possible to suppress a decrease in waterproofing property due to size of the protruding range of the protruding portions 43.

The through holes 33 and the protruding portions 43 are provided on both surfaces of a plate surface of each portion to be waterproofed 34.

With this configuration, it is possible to suppress deterioration of waterproofing property on both surfaces of the plate surface of the portion to be waterproofed 34. Also, the thickness of the first waterproofing portions 40 in the regions of the through holes 33 can be increased.

The terminal portions 26A and 26B each have a width dimension larger than that of a portion of the circuit section 21 with which the first waterproofing portion 40 is in intimate contact.

With this configuration, in a configuration in which it is not easy to attach a packing made of rubber or the like due to size of the width dimension of the terminal portions 26A and 26B, waterproofing can be achieved without using the packing.

Portions between the terminal portions 26A and 26B and respective main body portions 28 in the circuit section 21 are bent in a crank shape.

With this configuration, in a configuration in which there is a concern about adhesion to the portions to be waterproofed 34 during resin molding because the circuit section 21 has crank shapes, it is possible to suppress entry of water from the outside.

The circuit section 21 includes plate-shaped metal bus bars 25A and 25B, the terminal portions 26A and 26B are formed on the respective bus bars 25A and 25B, and the first waterproofing portions 40 and the second waterproofing portion 50 are in intimate contact with the bus bars 25A and 25B.

With this configuration, it is possible to prevent water from entering the bus bars 25A and 25B through which a relatively large current flows.

### Other Embodiments

The technique described in the present specification is not limited to the embodiment described by the above description and the drawings, and the following embodiments are also included in the technical scope of the technique described in the present specification.

The first waterproofing portion 40 is made of a polyester-based elastomer resin containing an adhesive component, but the present disclosure is not limited to this. The first waterproofing portion 40 may also be made of another resin containing an adhesive component.

Printed circuit boards each having a conduction path made of copper foil or the like printed on an insulating plate may also be stacked to form a circuit section on the bus bars 25A and 25B.

The connection portions 31 are configured to extend in a direction orthogonal to the terminal portions 26A and 26B and the main body portions 28, but the present disclosure is not limited to this configuration. A configuration including connection portions that extend in a direction intersecting the terminal portions 26A and 26B and main body portions 28 may also be employed.

The bus bars 25A and 25B respectively include terminal portions 26A and 26B, and each include the main body portion 28 and the connection portion 31. However, at least the portions to be waterproofed 34 that are waterproofed by the first waterproofing portions 40 may also be formed of the bus bars, and the terminal portions 26A and 26B and the like may also be formed of separate members. What is claimed is:

1. A circuit unit, comprising:
a circuit section that includes a terminal portion connectable to an external terminal and a main body portion on which an electronic component is mounted, and in which a portion between the main body portion and the terminal portion is a portion to be waterproofed that is made of a plate-shaped metal;
a first waterproofing portion that is in intimate contact with the portion to be waterproofed of the circuit section, and that is made of resin containing an adhesive component; and
a second waterproofing portion that is made of resin, and that is in intimate contact with the circuit section and an outer surface of the first waterproofing portion,
wherein the portion to be waterproofed includes a recessed portion into which the first waterproofing portion can enter, and
a protruding portion protruding outward is formed on an outer surface of a portion of the first waterproofing portion that overlaps the recessed portion.

2. The circuit unit according to claim 1, wherein the width of the protruding portion is larger than a range of the recessed portion that overlaps the protruding portion.

3. The circuit unit according to claim 1, wherein the recessed portion and the protruding portion are provided on both surfaces of a plate surface of the portion to be waterproofed.

4. The circuit unit according to claim 1, wherein the recessed portion is a through hole that penetrates the portion to be waterproofed.

5. The circuit unit according to claim 1, wherein the terminal portion has a width dimension larger than that of a portion of the circuit section with which the first waterproofing portion is in intimate contact.

6. The circuit unit according to claim 1, wherein a portion between the terminal portion and the main body portion in the circuit section is bent in a crank shape.

7. The circuit unit according to claim 1, wherein the circuit section includes a plate-shaped metal bus bar, the terminal portion and the portion to be waterproofed are formed on the bus bar, and the first waterproofing portion and the second waterproofing portion are in intimate contact with the bus bar.

8. An electrical junction box, comprising:
the circuit unit according to claim 1;
a heat dissipation member that is superposed on the circuit unit; and
a sealing member that is sandwiched between the circuit unit and the heat dissipation member.

9. A production method of a circuit unit, comprising:
a first waterproofing step of bringing a first waterproofing portion made of resin containing an adhesive component into intimate contact with a plate-shaped metal portion to be waterproofed that is provided between a terminal portion connectable to an external terminal and an electronic component in a circuit section that includes the terminal portion and a main body portion on which the electronic component is mounted; and
a second waterproofing step of forming a second waterproofing portion by bringing resin into intimate contact with the circuit section and the first waterproofing portion,
wherein, in the first waterproofing step, the resin containing the adhesive component enters a recessed portion formed in the portion to be waterproofed, and a protruding portion protruding outward is formed on the outer surface of the first waterproofing portion in the region of the recessed portion.
